(19) United States
(12) Patent Application Publication
(10) Pub. No.: US 2007/0146036 A1
(43) Pub. Date: Jun. 28, 2007

(54) DELAY CHAIN CAPABLE OF REDUCING SKEW BETWEEN INPUT AND OUTPUT SIGNALS

(76) Inventor: Geun Tae Kwon, Gyeonggi-do (KR)

Correspondence Address: SHERR & NOURSE, PLLC, 620 HERNDON PARKWAY, SUITE 200, HERNDON, VA, 20170, US

(21) Appl. No.: 11/616,813

(22) Filed: Dec. 27, 2006

(30) Foreign Application Priority Data
Dec. 28, 2005 (KR) 10-2005-0131390

(51) Int. Cl. H03H 11/26

(52) U.S. Cl. 327/285

(57) ABSTRACT

Embodiments relate to a delay chain that may reduce skew between input and output signals. In embodiments, the delay chain may include N inverters connected to each other in series between an input terminal and an output terminal (N is a positive even number integer). A gate of the PMOS transistor of an inverter arranged in the odd order from the input terminal of the N inverters may be connected to the input terminal commonly. A gate of the NMOS transistor of the inverter arranged in the even order from the input terminal of the N inverters may be connected to a reverse input terminal (IN/) commonly, which outputs a reverse signal of the input terminal. Since a substrate of the PMOS transistor of the inverter arranged in the even order from the input terminal of N inverters may be connected to the gate of the PMOS transistor, and a substrate of the NMOS transistor of the inverter arranged in the odd order from the input terminal may be connected to the gate of the NMOS transistor, the threshold voltage is lower than a voltage of other transistors. The rising skew and the falling skew between the output response of the delay chain and the input signal may be prevented from being increased by the operational voltage. Although the operational voltage of the semiconductor IC element for a mobile device may be lowered, the output response of the delay chain may not be lowered and an operational speed of the semiconductor IC element may not be reduced.

The present application claims priority under 35 U.S.C. 119 and 35 U.S.C. 365 to Korean Patent Application No. 10-2005-0131390 (filed on Dec. 28, 2005), which is hereby incorporated by reference in its entirety.

### BACKGROUND

Since a mobile device may have a low power consumption, an operational voltage of a semiconductor IC element used in the mobile device may be reduced. However, if the operational voltage of the semiconductor element is reduced, an operational speed may also be reduced. In particular, an operational speed reduction of the delay chain used in semiconductor IC elements may be a problem.

FIG. 1 is an example circuit diagram illustrating a related art delay chain. A buffer circuit having a plurality of inverters that may be connected to each other in series may be a delay chain which has no reversed/inverted phase between input and output signals and may be operated at a relatively fast speed.

Referring to FIG. 1, a related art buffer type delay chain 10 may include four inverters INT1, INT2, INT3, and INT4, connected in series between an input terminal IN and an output terminal OUT. Each inverter may include PMOS and NMOS transistors that may be connected between a power terminal and a ground terminal. A substrate of all PMOS transistors P1, P2, P3, and P4 may be connected to the power terminal, and a substrate of NMOS transistors N1, N2, N3, and N4 may be connected to the ground terminal.

An input signal outputted from the input terminal may be provided to a gate of PMOS transistor P1 and a gate of the NMOS transistor N1 of first inverter INT1 through node n1. An output of first inverter INT1 may be connected to an input (node n2) of second inverter INT2, and an output of second inverter INT2 may be connected to an input (node n3) of third inverter INT3. An output of third inverter INT3 may be connected to an input (node n4) of fourth inverter INT4, and an output of fourth inverter INT4 may be connected to the output terminal OUT through node n5. Since each input and output of four inverters INT1-4 between the input terminal IN and the output terminal OUT in related art delay chain 10 may be connected to each other in series, input and output signals may be represented as wavelengths, as shown in FIG. 2.

Referring to FIG. 2, when an input signal is changed from “0” to “1”, NMOS transistor N1 of first inverter INT1, PMOS transistor P2 of second inverter INT2, NMOS transistor N3 of third inverter INT3 and PMOS transistor P4 of fourth inverter INT4 may be sequentially turned on, and the output signal may be changed from “0” to “1”. There may be a delay between a point in time when the input signal is changed from “0” to “1” and a time when the output signal is changed from “0” to “1”, which may be as much as D1. D1 may be a sum of the turn-on time of each transistor. That is, a rising skew of D1 may exist between the input and output signals. However, when the input signal is changed from “1” to “0”, PMOS transistor P1 of first inverter INT1, NMOS transistor N2 of second inverter INT2, PMOS transistor P3 of third inverter INT3 and NMOS transistor N4 of fourth inverter INT4 may be sequentially turned on, and the output signal may be changed from “1” to “0”. There may be a delay between a point in time when the input signal is changed from “1” to “0” and a time when the output signal is changed from “1” to “0”, which may be as much as D2. That is, a falling skew between the input and output signals may be D2.

Rising skew D1 and falling skew D2 may increase as a power voltage decreases. In particular, since falling skew D2 may be represented as a response speed delay of the semiconductor IC element, falling skew D2 may have influence on an element error.

### SUMMARY

Embodiments relate to a semiconductor device manufacturing technology. Embodiments relate to a delay chain capable of reducing skew between input and output signals.

Embodiments relate to a delay chain for solving an operational speed reduction of an IC element when an operational voltage of the IC element is lowered.

Embodiments relate to a delay chain of a new structure for preventing an operational speed of a semiconductor IC element from being reduced according to a late output response of the delay chain.

In embodiments, a delay chain may include N inverters that may be connected to each other in series between an input terminal and an output terminal (N is a positive even number integer). A gate of the PMOS transistor of an inverter arranged in the odd order from the input terminal of the N inverters may be connected to the input terminal commonly. A gate of the NMOS transistor of the inverter arranged in the even order from the input terminal of the N inverters may be connected to a reverse input terminal (IN/) commonly, which outputs a reverse signal of the input terminal. Since a substrate of the PMOS transistor of the inverter arranged in the even order from the input terminal of N inverters may be connected to the gate of the PMOS transistor, and a substrate of the NMOS transistor of the inverter arranged in the odd order from the input terminal may be connected to the gate of the NMOS transistor, the threshold voltage may be lower than a voltage of other transistors.

### BRIEF DESCRIPTION OF THE DRAWINGS

FIG. 1 is an example circuit diagram illustrating a related art delay chain.

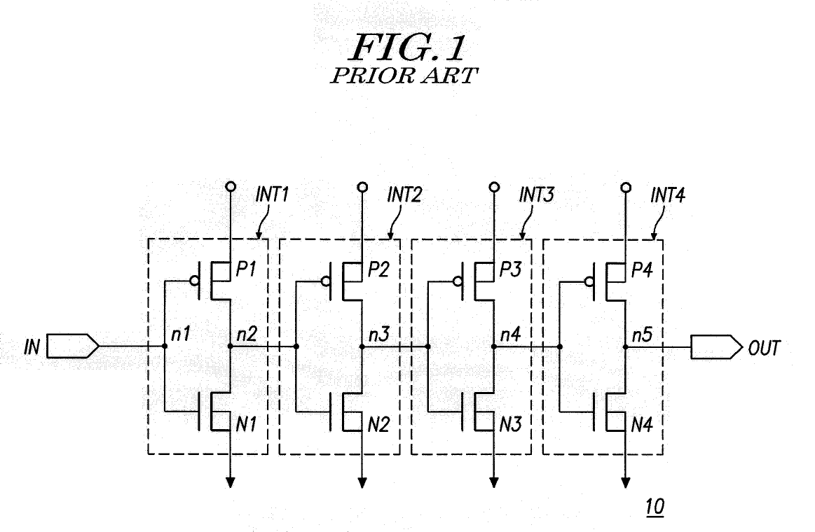

FIG. 2 is an example diagram illustrating waveforms of input and output signals of a related art delay chain.

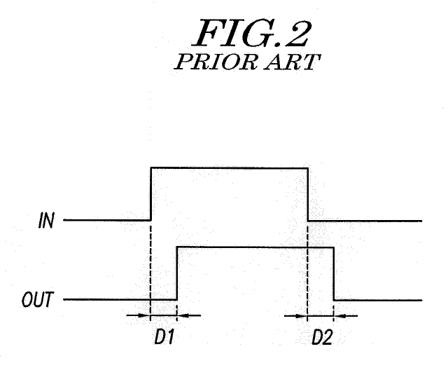

FIG. 3 is an example circuit diagram illustrating a delay chain in accordance with embodiments.

FIG. 4 is an example diagram illustrating waveforms of input and output signals of a delay chain in accordance with embodiments.

### DETAILED DESCRIPTION OF EMBODIMENTS

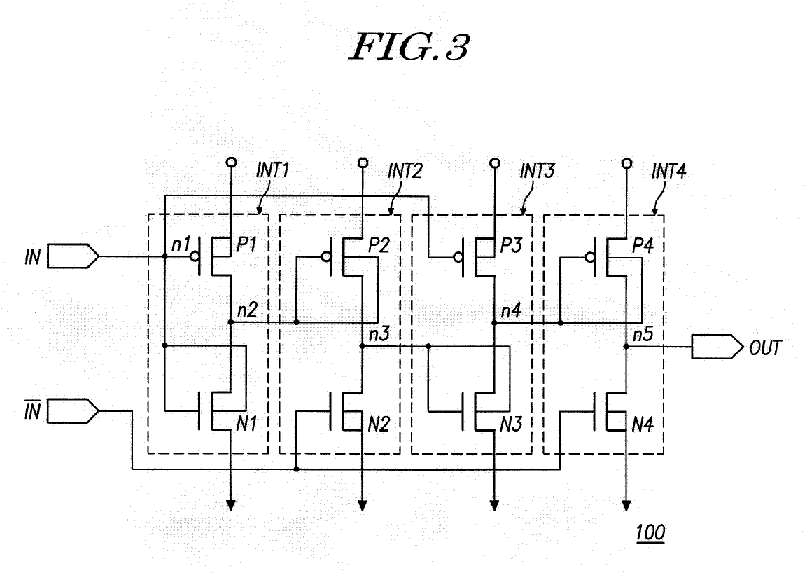

A plurality of inverters INT1-INT4 may be connected to each other in series between an input terminal IN and an output terminal OUT in delay chain 100. Although delay chain 100 may have four inverters, as illustrated in FIG. 3, in embodiments, a number of delay chains may be modified. If the delay chain does not have a reversed/inverted phase between an input signal and an output signal, the delay chain may have an even number of inverters.

Referring to FIG. 3, according to embodiments, delay chain 100 may include a reverse input terminal IN/ which may output an inverted signal of the input terminal IN. A signal of the input terminal IN may be provided to gates of PMOS transistor P1 and NMOS transistor N1 of inverter INT1 which may be a first inverter in the series and coupled to the input terminal IN. A gate of PMOS transistor P3 of inverter INT3 which may be arranged in the odd order from the input terminal IN may receive the input signal at the same time. However, an inverted signal of the reverse input terminal IN/ may be simultaneously provided to gates of NMOS transistors N2 and N4 of inverters INT2 and INT4, which may be arranged in an even order from the input terminal IN.

Moreover, an output of the first inverter INT1 may be connected to a gate of PMOS transistor P2 through node n2. An output of second inverter INT2 may be connected to a gate of NMOS transistor N3 through node n3. An output of third inverter INT3 may be connected to a gate of PMOS transistor P4 of fourth inverter INT4 through node n4. An output of fourth inverter INT4 may be connected to the output terminal OUT through node n5.

According to embodiments, in delay chain 100, a substrate of NMOS transistor N1 of first inverter INT1 may be connected to a gate of NMOS transistor N1, and not to ground. A substrate of PMOS transistor P2 of second inverter INT2 may be connected a gate of PMOS transistor P2 through node n2, and not to power. A substrate of NMOS transistor N3 of third inverter INT3 may be connected to a gate of NMOS transistor N3 through node n3, and not to ground. A substrate of PMOS transistor P4 of the fourth inverter may be connected to a gate of PMOS transistor P4 through node n4, and not to a power source. A substrate of the remaining transistors may be connected to the power or the ground. In embodiments, a ground of transistors N1, P2, N3 and P4, except for the PMOS transistor of the odd inverter that may have a common input signal and the NMOS transistor of the even inverter that may commonly receive an inverted signal, may be configured as above, in which case an operational speed of the transistor may be increased since a threshold voltage of the transistor may be lowered than a voltage of a stand-by state.

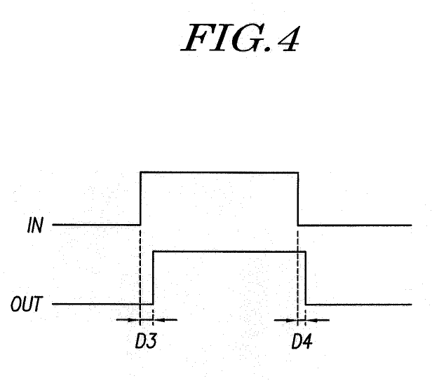

A waveform of input and output signals of a delay chain is shown in FIG. 4.

If an input signal is changed from “0” to “1”, NMOS transistor N1 of the first inverter may be turned on. PMOS transistor P2 of the second inverter may be turned on based on an output signal “0” of the first inverter. Then NMOS transistor N3 of the third inverter and PMOS transistor P4 of the fourth inverter may be sequentially turned on. Accordingly, the output signal may be changed from “0” to “1”. According to embodiments, the threshold voltage may be lowered by connecting the ground of transistors N1, P2, N3 and P4 to the gate of transistors N1, P2, N3 and P4, respectively. Rising skew D3, which may be a difference between a time point when an input signal is changed from “0” to “1” and a time point when an output signal is changed from “0” to “1,” may thus be reduced. In embodiments, it may be less than related art rising skew D1. Accordingly, although an operational voltage of the transistor may be lowered, the rising skew of delay chain 100 may not be increased.

If the input signal changes from “1” to “0”, PMOS transistors P1 and P3 of first and third inverters INT1 and INT3, which may have the gate connected to the input terminal IN, and NMOS transistors N2 and N4 of second and fourth inverters INT2 and INT4, which may have the gate connected to the reverse input terminal IN/, may be simultaneously turned on. That is, any one of transistors P1, N2, P3 and N4 of all inverters included in delay chain 100 may be turned on at the same time. Accordingly, a falling skew, which may be a difference between a time point when the input signal is changed from “1” to “0” and a time point when the output signal is changed from “1” to “0,” may be reduced. In embodiments, the falling skew may be reduced to a time delay associated with a transistor turn on time, and may be represented by time period “D4” shown in FIG. 4. Accordingly, the falling skew, which may influence a response speed of a semiconductor IC element, may be prevented from being increased by the decrease in operational voltage.

In accordance with embodiments, the rising skew and the falling skew between the output response of the delay chain and the input signal may be prevented from being increased by the operational voltage drop by changing a transistor connection structure of each inverter connected to the input terminal and the reverse terminal, and changing a ground connection structure of the transistor. Accordingly, although the operational voltage of the semiconductor IC element for a mobile device may be lowered, an output response of the delay chain may not be lowered and the operational speed of the semiconductor IC element may not be reduced.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device comprising:
a plurality of inverters electrically connected to each other in series between an input terminal and an output terminal, wherein
gates of PMOS transistors of odd numbered inverters of the plurality of inverters arranged in order from the input terminal are commonly connected to the input terminal, and
gates of NMOS transistors of even numbered inverters of the plurality of inverters arranged in order from the input terminal are commonly connected to an inverse input terminal, which outputs an inverted signal of the input terminal.

2. The device of claim 1, wherein a signal of an output terminal is delayed relative to a signal of an input terminal.

3. The device of claim 1, wherein the plurality of inverters comprises an even number of inverters.

4. The device of claim 1, wherein a substrate of the PMOS transistor of the even numbered inverters of the plurality of inverters is connected to a gate of the same PMOS transistor, and a substrate of the NMOS transistor of the odd numbered inverters of the plurality of inverters is connected to a gate of the same NMOS transistor.

5. The device of claim 1, wherein the gate of the NMOS transistor of a first inverter of the plurality of inverters is connected to the input terminal.

6. A method, comprising:
connecting a plurality of inverters to each other in series between an input terminal and an output terminal;
connecting gates of PMOS transistors of odd numbered inverters of the plurality of inverters arranged in order from the input terminal to the input terminal; and
connecting gates of NMOS transistors of even numbered inverters of the plurality of inverters arranged in order from the input terminal to an inverse input terminal, which outputs an inverted signal of the input terminal.

7. The method of claim 6, further comprising connecting a substrate of the PMOS transistor of the even numbered inverters of the plurality of inverters to a gate of the same PMOS transistor, and connecting a substrate of the NMOS transistor of the odd numbered inverters of the plurality of inverters to a gate of the same NMOS transistor.

8. The method of claim 7, further comprising connecting the gate of the NMOS transistor of a first inverter of the plurality of inverters directly to the input terminal.

9. The method of claim 6, wherein the plurality of inverters comprises an even number of inverters.

10. A device comprising:
first, second, third, and fourth of inverters electrically connected to each other in series between an input terminal and an output terminal, wherein
gates of PMOS transistors of the first and third inverters are commonly connected to the input terminal, and
gates of NMOS transistors of the second and fourth inverters are commonly connected to an inverse input terminal, which outputs an inverted signal of the input terminal.

11. The device of claim 10, wherein a substrate of the PMOS transistor of the second and fourth inverters is connected to a gate of the PMOS transistor of the second and fourth inverters, respectively, and a substrate of the NMOS transistor of the first and third inverters is connected to a gate of the NMOS transistor of the first and third inverters, respectively.

12. The device of claim 11, wherein the gate of the NMOS transistor of the first inverter is connected to the input terminal.
